(19) United States
(12) Patent Application Publication
(10) Pub. No.: US 2015/0156914 A1
(43) Pub. Date: Jun. 4, 2015

(54) HEAT RADIATION SYSTEM FOR POWER SEMICONDUCTOR MODULE

(71) Applicant: SAMSUNG ELECTRO-MECHANICS CO., LTD., Suwon-Si (KR)

(72) Inventors: Young Hoon KWAK, Suwon-Si (KR); Chang Seob Hong, Suwon-Si (KR); Young Ki Lee, Suwon-Si (KR)

(73) Assignee: SAMSUNG ELECTRO-MECHANICS CO., LTD., Suwon-Si (KR)

(21) Appl. No.: 14/327,466

(22) Filed: Jul. 9, 2014

(30) Foreign Application Priority Data
Dec. 2, 2013 (KR) 10-2013-0148672

(51) Int. Cl. H05K 7/20

(52) U.S. Cl. CPC H05K 7/2089; H05K 7/209

(57) ABSTRACT

Disclosed herein is a heat radiation system including: a frame; a partition plate disposed across the frame and including an inlet for supplying a cooling medium, a plurality of louvers extended radially from a circumference of the inlet, and a slot formed at a circumference of an edge thereof; a diffusion chamber defined by the frame and the partition plate; a lower plate disposed at a lower portion of the frame so as to be spaced apart from the partition plate by a predetermined interval and including an outlet for discharging the cooling medium; and a recovery chamber defined by the frame, the partition plate, and the lower plate and being in fluid communication with the diffusion chamber. Particularly, the diffusion chamber and the recovery chamber may be partitioned from each other by the partition wall to form a double

### CROSS REFERENCE TO RELATED APPLICATION

This application claims the benefit of Korean Patent Application No. 10-2013-0148672, filed on Dec. 2, 2013, entitled “Heat radiation system for power semiconductor module”, which is hereby incorporated by reference in its entirety into this application.

### BACKGROUND OF TEE INVENTION

1. Technical Field

The present invention relates to a heat radiation system for a power semiconductor module.

2. Description of the Related Art

In accordance with an increase in energy consumption around the world, an efficient use of restricted energy has attracting much attention. Therefore, power semiconductor modules having various structures have been used in all home appliances such as an air conditioner, a refrigerator, and the like, and the user of the power semiconductor modules have been widely increased. Since the power semiconductor module may minimize used power/energy as well-known, it has been necessarily used in environment-friendly products.

As described above, in accordance with an increase in the use of the power semiconductor module, a market's demand for a power semiconductor module having a multi-function and a small size has increased. Therefore, a heat generation problem of an electronic component has deteriorated performance of the entire module. In order to secure high efficiency and high reliability of the power semiconductor module, a high heat radiation power module package structure capable of solving the heat generation problem has been demanded.

A module in which a power device including an insulated gate bipolar mode transistor (hereinafter, referred to as IGBT) generating a large amount of heat is mounted is attached onto a heat radiation system using thermal grease or a bonding scheme between metals. That is, the heat generated from the power device is radiated by the heat radiation system attached to a bottom surface of the power device. However, the thermal grease, a solder, a thermal interface material (TIM), or the like, deteriorates heat radiation characteristics to limit heat radiation characteristics of the power semiconductor module.

Therefore, Patent Document 1 according to the prior art has disclosed a heat radiation structure of circulating cooling water in a cooling passage including an inverter case, a cooling fin, and a condenser case to absorb heat generated by the IGBT and radiate the heat to an outlet. That is, the cooling water has a moving path through which it is simply discharged from an inlet to the outlet through the cooling passage. In this case, the cooling water may be discharged to the outlet in a state in which heat is not sufficiently exchanged between the cooling water and the power device, and when the cooling water stays in the cooling passage for a long period of time, the heat is not rapidly radiated, such that there is a limitation in lowering a temperature to a predetermined level or less.

### PRIOR ART DOCUMENT

### Patent Document

(Patent Document 1) Korean Patent Laid-Open Publication No. 10-2006-0036400

### SUMMARY OF THE INVENTION

The present invention has been made in an effort to provide a heat radiation system for a power semiconductor module that is capable of certainly securing a contact opportunity between a cooling medium and a heat radiation substrate by controlling a moving path of the cooling medium and is capable of improving heat exchange capability by smoothing circulation of the cooling medium.

According to a preferred embodiment of the present invention, there is provided a heat radiation system including: a frame; a partition plate disposed across the frame and including an inlet for supplying a cooling medium, a plurality of louvers extended radially from a circumference of the inlet, and a slot formed at a circumference of an edge thereof; a diffusion chamber defined by the frame and the partition plate; a lower plate disposed at a lower portion of the frame so as to be spaced apart from the partition plate by a predetermined interval and including an outlet for discharging the cooling medium; and a recovery chamber defined by the frame, the partition plate, and the lower plate and being in fluid communication with the diffusion chamber.

Particularly, the diffusion chamber and the recovery chamber may be partitioned from each other by the partition wall to form a double-layer structure.

An upper portion of the frame may be closed by a heat radiation substrate of a power semiconductor module, such that heat exchange is made through a contact between a low temperature cooling medium supplied to the diffusion chamber and the heat radiation substrate.

The diffusion chamber may be in fluid communication with the recovery chamber in order to transfer a high temperature cooling medium contacting the heat radiation substrate to the recovery chamber.

The inlet may be formed at a central region of the partition plate so as to provide diffusion and a predetermined staying time of the cooling medium.

The partition plate may include the plurality of louvers protruding thereon in a vertically upward direction.

The plurality of louvers may have a predetermined height so as to support and/or contact the heat radiation substrate that is to be seated on the upper portion of the frame.

The plurality of louvers may be radially extended so as to be curved from a central region of the partition plate, for example, a circumference of the inlet, toward the edge of the partition plate.

The plurality of louvers may be disposed so that a distance between adjacent louvers becomes wider from a central region of the partition plate toward the edge of the partition plate.

One louver and a louver adjacent thereto may have one or more fin disposed therebetween.

The fin may be disposed between distal ends of the plurality of louvers.

The inlet may be extended downwardly from the partition plate through the lower plate to supply the cooling medium from the outside of the heat radiation system.

The heat radiation system may further include: a housing having a hollow part; and a cover closing a lower portion of the housing. The power semiconductor module including the heat radiation substrate and the heat radiation system may be inserted into the hollow part of the housing.

The cover may include penetration holes formed therein so as to pass the inlet and the outlet of the heat radiation system therethrough, respectively.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view schematically showing a heat radiation system for a power semiconductor module according to a preferred embodiment of the present invention;

FIG. 2 is a view of the heat radiation system for a power semiconductor module shown in FIG. 1;

FIG. 3 is a cross-sectional view of a heat radiation system on which a heat radiation substrate is mounted;

FIG. 4 is an enlarged cross-sectional view of the heat radiation system for a power semiconductor module according to a preferred embodiment of the present invention; and

FIG. 5 is a plan view of the heat radiation system for a power semiconductor module according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

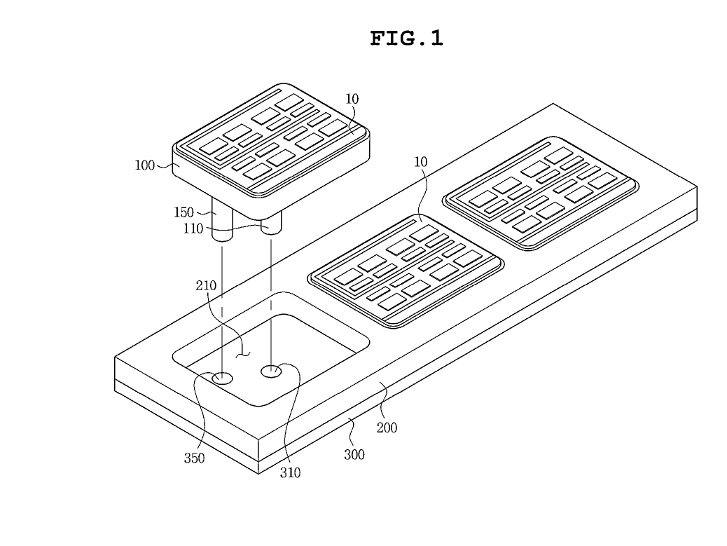

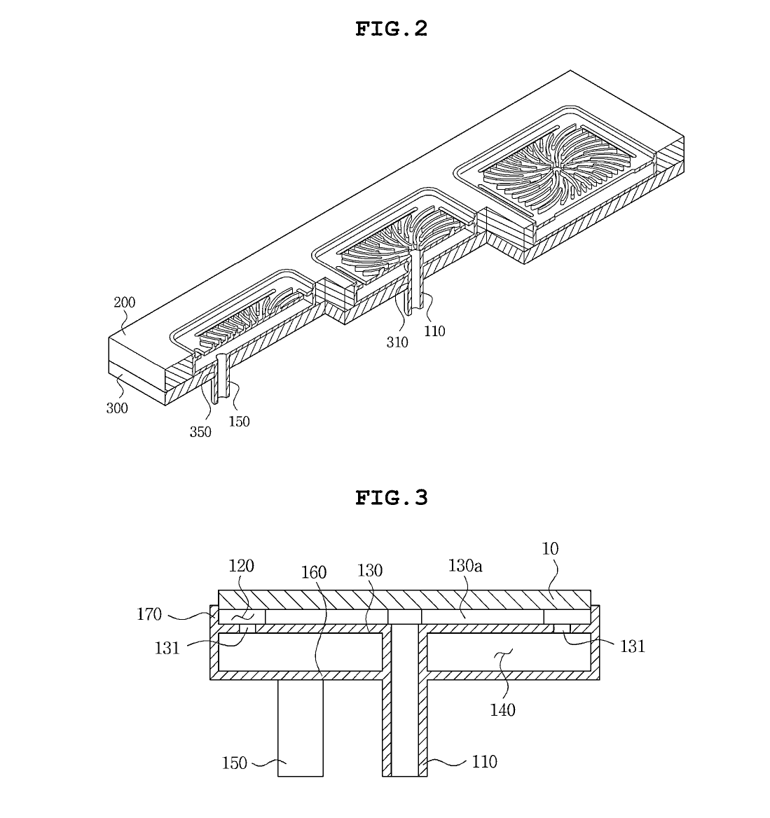

FIG. 1 is a perspective view of a heat radiation system for a power semiconductor module according to a preferred embodiment of the present invention viewed from the top; and FIG. 2 is a cut-away perspective view for confirming a coupled state of the heat radiation system except for a heat radiation substrate.

Referring to FIGS. 1 and 2, power semiconductor devices of a high side and a low side of a power semiconductor module are mounted on a heat radiation substrate 10. The heat radiation system 100 according to a preferred embodiment of the present invention is bonded to a lower substrate of the heat radiation substrate 10.

As shown in FIGS. 1 and 2, the heat radiation system for a power semiconductor module according to a preferred embodiment of the present invention may further include a housing 200 and a cover 300 so that the heat radiation substrate 10 and the heat radiation system 100 may be mounted integrally with each other in an electronic product. The housing 200 includes one or more hollow part 210, which provides a space for inserting the heat radiation substrate 10 having the power semiconductor module mounted thereon and the heat radiation system 100 into the housing 200. A lower portion of the housing 200 is closed by the cover 300, which includes two penetration holes 310 and 350 formed therein so as to correspond to the respective hollow parts 210 of the housing 200. Here, the penetration hole 310 assists in insertion and penetration of an inlet 110 of a cooling medium of the heat radiation system 100, and the penetration hole 350 assists in insertion and penetration of an outlet 150 of the cooling medium of the heat radiation system 100. Here, the cooling medium may be a gas or liquid state fluid and be configured of air, cooling water, refrigerant, and the like.

FIGS. 1 and 2 show a power semiconductor module for a three-phase motor in which three power semiconductor modules are mounted in one housing 200. However, the heat radiation system for a power semiconductor module according to a preferred embodiment of the present invention is not limited thereto, but may include the housing 200 having one or more hollow part so that it may be used in various types of power semiconductor modules such as a single-phase motor, and the like.

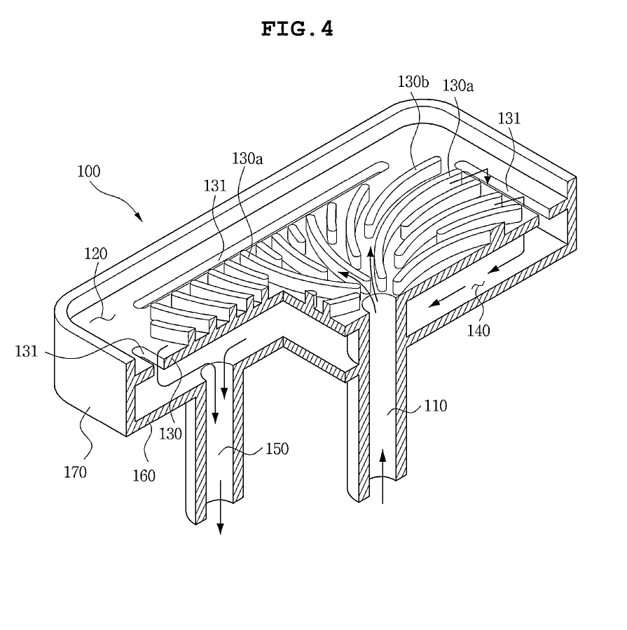

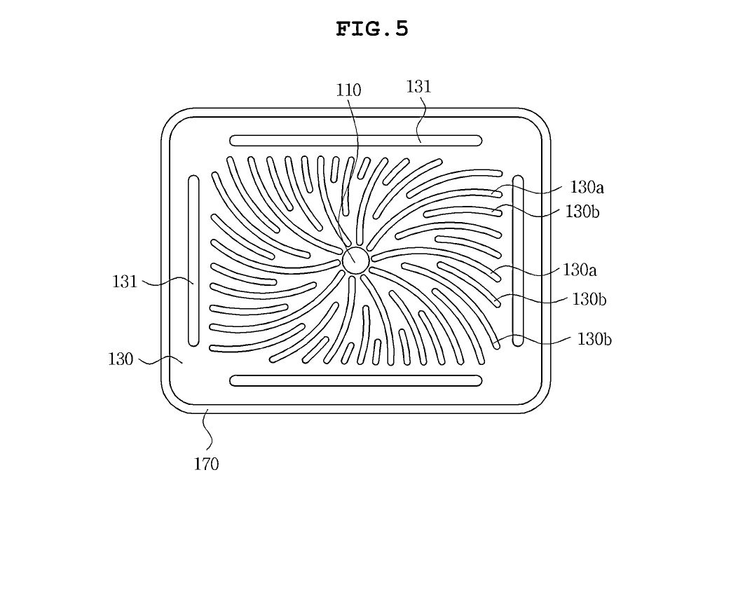

FIG. 3 is a cross-sectional view of a heat radiation system on which a heat radiation substrate is mounted; and FIG. 4 is an enlarged cross-sectional view of the heat radiation system for a power semiconductor module except for the heat radiation substrate.

The heat radiation system 100 according to a preferred embodiment of the present invention is configured to include a diffusion chamber 120 that is in fluid communication with the inlet 110 of the cooling medium; and a recovery chamber 140 that is in fluid communication with the outlet 150 of cooling medium. That is, the heat radiation system includes the diffusion chamber 120 and the recovery chamber 140 disposed in a double-layer structure. The heat radiation system 100 having the double-layer structure includes the diffusion chamber 120 to which a low temperature cooling medium is supplied to perform heat exchange and the recovery chamber 140 in which a heat-exchanged high temperature cooling medium is collected so as to prevent the high temperature cooling medium and a continuously supplied low temperature cooling medium from being mixed with each other.

In addition, the heat radiation system 100 includes a partition plate 130 disposed between the diffusion chamber 120 and the recovery chamber 140 in order to prevent the low temperature cooling medium supplied to the diffusion chamber 120 and the high temperature cooling medium passing through the diffusion chamber 120 and then transferred to the recovery chamber 140 from being mixed with each other. The partition plate 130 serves to partition the diffusion chamber 120 and the recovery chamber 140 from each other as shown in FIGS. 3 and 4 to prevent the cooling media from being mixed with each other and serves to connect the diffusion chamber 120 and the recovery chamber 140 to each other so as to be in fluid communication with each other.

In detail, the partition plate 130 includes one or more slot 131 formed along a circumference thereof The slot 131 is used as a channel moving the cooling medium dispersed while passing through the diffusion chamber 120 to the recovery chamber 140.

The heat radiation system 100 according to a preferred embodiment of the present invention includes a frame 170 having a predetermined thickness. An upper portion of the frame 170 is closed by the heat radiation substrate 10 of the power semiconductor module as shown in FIG. 3, and a lower portion thereof is closed by a lower plate 160 having two penetration holes.

The frame 170 includes the partition plate 130 disposed between the heat radiation substrate 10 of the power semiconductor module and the lower plate 160. The partition plate 130 may be spaced apart from the heat radiation substrate 10 by a predetermined interval to form the diffusion chamber 120, and may also be spaced apart from the lower plate 160 by a predetermined interval to form the recovery chamber 140. As shown, the frame 170 supports the heat radiation substrate 10, the partition plate 130, and the lower plate 160 so as to be spaced apart from each other and prevents leakage of the cooling medium to a channel other than a defined channel.

In the heat radiation system 100 according to a preferred embodiment of the present invention, when the heat radiation substrate 10, the lower plate 160, and the partition plate 130 are mounted in the frame 170, they may be coupled to the frame 170 by welding, an O-ring, a waterproof and heat resistant adhesive, or the like, in order to prevent the leakage of the cooling medium.

In detail, the cooling medium is introduced into the diffusion chamber through the inlet 110 to contact the power semiconductor module coupled to an upper portion of the heat radiation system 100. The relatively low temperature cooling medium contacts heat generated from the power semiconductor module through the heat radiation substrate 10, such that heat exchange is made between the heat radiation substrate 10 and the cooling medium. The high temperature cooling medium subjected to the heat exchange is forcibly transferred to the recovery chamber 140 along the slot 131 of the partition plate 130 and is then discharged to the outside through the outlet 150. The cooling medium is moved as described above, thereby making it possible to rapidly cool the heat generated from the power semiconductor module. In FIG. 4, an arrow indicates a moving path of the cooling medium.

The inlet 110 is lengthily extended downwardly from the partition plate 130 through the lower plate 160 and is extended to the penetration hole 310 of the cover 300 shown in FIG. 2. Preferably, the inlet 110 is disposed at a central region of the partition plate 130. Since the inlet 110 is disposed at a central region of the diffusion chamber 120, the cooling medium may be rapidly and uniformly diffused over a lower surface of the heat radiation substrate, a contact opportunity between the cooling medium and the lower surface of the heat radiation substrate may be improved, and a time in which the cooling medium stays in the diffusion chamber is not excessively long. For example, when the inlet 110 of the cooling medium is formed at an edge of one side of the partition plate 130 and the slot 131 is disposed at an edge of the other side thereof facing the edge of the one side thereof, a time in which the cooling medium stays in the diffusion chamber 120 while moving from the inlet 110 to the slot 131 spaced apart from the inlet 110 by the longest distance is long, such that a long time is required for the heat-exchanged high temperature cooling medium.

The outlet 150 is lengthily extended downwardly from the lower plate 160 and is extended to the penetration hole 350 of the cover 300 shown in FIG. 2.

Preferably, the heat radiation system according to a preferred embodiment of the present invention is designed so as to assist in diffusion movement of the cooling medium supplied to the diffusion chamber 120. The diffusion of the cooling medium will be described in more detail with reference to FIG. 5.

FIG. 5 is a plan view of the heat radiation system for a power semiconductor module shown in FIG. 4.

Referring to FIG. 5, the heat radiation system 100 according to a preferred embodiment of the present invention includes a plurality of louvers 130a formed on the partition plate 130. The louver 130a is extended from the inlet 110 toward the slot 131. That is, the louver 130a is extended from a central region of the partition plate 130 to an edge thereof.

Preferably, the plurality of louvers 130a protrude on a flat partition plate 130 in a vertically upward direction and contact the heat radiation substrate 10 (See FIG. 3) that is to be seated on the frame 170 of the heat radiation system. The louvers 130a contact the heat radiation substrate as described above to increase a heat radiation area of the heat radiation substrate, such that a contact opportunity between the heat radiation substrate and the cooling medium is improved, thereby making it possible to expect excellent cooling efficiency. Further, the louvers 130a support the heat radiation plate in the frame 170, thereby making it possible to prevent a sag phenomenon of the heat radiation substrate. That is, a protrusion height of the louver 130a needs to be the same as or smaller than a distance between the partition plate 130 and the heat radiation substrate that is to be mounted in the frame 170.

The plurality of louvers 130a are radially formed so as to be curved from the central region of the partition plate, for example, a circumference of the inlet 111, toward an edge of the partition plate, as shown in FIG. 5. Particularly, a distance between the louvers 130 becomes wider toward the edge of the partition plate to increase a cross-sectional area between the louvers 130a. When the cross-sectional area between the louvers 130a is increased, a movement pressure drop is decreased, such that a flow rate of supplied cooling medium is increased.

In addition, the plurality of louvers 130a include one or more fin 130b additionally disposed therebetween. One or more fin 130b forcibly decreases a cross-sectional area formed between distal ends of the louvers 130a, thereby making it possible to increase a flow velocity of the cooling medium. That is, the high temperature cooling medium contacting the heat radiation substrate, the louvers 130a, and the fin 130b may be rapidly moved toward the slot 131. The fin 130b is curved in a shape similar to that of the curved louver 130a.

As described above, the heat radiation system for a power semiconductor module according to a preferred embodiment of the present invention radially disperses the cooling medium introduced into the central region over an entire contact region of the heat radiation substrate, thereby making it possible to rapidly radiate the heat generated from the power semiconductor module.

According to a preferred embodiment of the present invention, a moving path of the cooling medium is limited by the louvers and the fin in the heat radiation system, thereby making it possible to uniformly disperse the cooling medium to a contact region with the heat radiation substrate as described above and rapidly discharge the high temperature cooling medium contacting the heat of the heat radiation substrate to the outside.

According to a preferred embodiment of the present invention, the heat radiation system having a double-layer structure is applied to separate introduction and discharge of the cooling medium from each other, thereby making it possible to efficiently accomplish the heat exchange between the cooling medium and the heat radiation substrate.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

1. A heat radiation system comprising:
a frame;
a partition plate disposed across the frame and including an inlet for supplying a cooling medium, a plurality of louvers extended radially from a circumference of the inlet, and a slot formed at a circumference of an edge thereof;
a diffusion chamber defined by the frame and the partition plate;
a lower plate disposed at a lower portion of the frame so as to be spaced apart from the partition plate by a predetermined interval and including an outlet for discharging the cooling medium; and
a recovery chamber defined by the frame, the partition plate, and the lower plate and being in fluid communication with the diffusion chamber,
wherein the diffusion chamber is disposed on the recovery chamber to form a double-layer structure.

2. The heat radiation system as set forth in claim 1, wherein an upper portion of the frame is closed by a heat radiation substrate of a power semiconductor module.

3. The heat radiation system as set forth in claim 1, wherein the diffusion chamber is in fluid communication with the recovery chamber through the slot of the partition plate.

4. The heat radiation system as set forth in claim 1, wherein the inlet is formed at a central region of the partition plate.

5. The heat radiation system as set forth in claim 1, wherein the plurality of louvers protrude on the partition plate in a vertically upward direction.

6. The heat radiation system as set forth in claim 1, wherein a protrusion height of the louver is the same as or smaller than a distance between the partition plate and the heat radiation substrate that is to be seated on the upper portion of the frame.

7. The heat radiation system as set forth in claim 1, wherein the plurality of louvers are radially extended so as to be curved from a central region of the partition plate toward the edge of the partition plate.

8. The heat radiation system as set forth in claim 1, wherein the plurality of louvers are disposed so that a distance between adjacent louvers becomes wider from a central region of the partition plate toward the edge of the partition plate.

9. The heat radiation system as set forth in claim 8, wherein the plurality of louvers include one or more fin additionally disposed therebetween.

10. The heat radiation system as set forth in claim 9, wherein the fin is disposed between distal ends of the plurality of louvers.

11. The heat radiation system as set forth in claim 1, wherein the inlet is extended downwardly from the partition plate through the lower plate.

12. The heat radiation system as set forth in claim 1, further comprising:
a housing having one or more hollow part assisting in seating the heat radiation system and a power semiconductor module; and
a cover disposed below the housing.

13. The heat radiation system as set forth in claim 12, wherein the cover includes penetration holes formed therein so as to pass the inlet and the outlet therethrough, respectively.
